(19) United States
(12) Patent Application Publication
(10) Pub. No.: US 2008/0038907 A1
(43) Pub. Date: Feb. 14, 2008

(54) Method for Fabricating Non-Volatile Memory Device

(76) Inventor: DOO SUNG LEE, Taebaek-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/782,729

(22) Filed: Jul. 25, 2007

(30) Foreign Application Priority Data
Aug. 9, 2006 (KR) 10-2006-0075422

(51) Int. Cl. H01L 21/425

(52) U.S. Cl. 438/524; 257/E21.473

(57) ABSTRACT

A method for manufacturing a non-volatile memory device is provided, including the step of performing an ion implantation process to form an impurity area in a field oxide area formed on a substrate, where the ion implantation process is performed at least two times while varying ion implantation angles relative to the substrate.

### CROSS-REFERENCE TO RELATED APPLICATION

The present application claims the benefit under 35 U.S.C. §119 of Korean Patent Application No. 10-2006-0075422, filed Aug. 9, 2006, which is hereby incorporated by reference in its entirety.

### BACKGROUND

Recently, as flash memory has become widely used, and the price competition for flash memory has increased, technologies to reduce the size of a semiconductor device have been actively developed. Among the technologies, a self aligned source (SAS) technology has been developed to reduce the size of the semiconductor device.

FIG. 1 is a plan view showing a memory cell where SAS technology is not employed, FIG. 2 is a plan view showing a memory cell where SAS technology is employed, and FIG. 3 is a cross-sectional view taken along line I-I′ of FIG. 2.

As shown in FIG. 1, field oxide areas 10, which are isolation areas, are formed in a bit line (BL) direction. Active areas 20 are defined between adjacent field oxide areas 10 to form devices thereon. Drain contacts 30 are formed in cells of the active areas 20.

Gate lines 40 are formed in a word line (WL) direction, and common source lines 50 are spaced apart from the gate lines 40 by a predetermined distance in parallel with the gate lines 40.

As shown in FIGS. 2 and 3, if a SAS technology is employed for the above memory cell, after a field oxide area 10 corresponding to the region for the common source line 50 is etched, ions are implanted into the resultant structure, thereby forming a SAS area 70.

In detail, according to the related technology, since impurities are implanted only in a vertical direction in order to form the SAS area 70, the impurities are irregularly distributed over the profile of the field oxide area 60. Accordingly, the junction resistance of the source in each cell is rapidly increased.

### BRIEF SUMMARY

Embodiments of the present invention provide a method for manufacturing a non-volatile memory device including an ion implantation process for constructing a common source. An embodiment provides a method for manufacturing a non-volatile device, in which an ion implantation process employed for forming a self-aligned source (SAS) area can be uniformly performed along the profile of a field oxide area.

According to an embodiment, a method for manufacturing a non-volatile memory device includes performing an ion implantation process to form an impurity area in a trench for a field oxide area formed on a substrate, wherein the ion implantation process is performed at least two times while varying ion implantation angles relative to the substrate.

In addition, according to an embodiment, a method for manufacturing a non-volatile memory device having a self aligned source includes performing a first ion implantation process to form a first impurity area on a bottom surface of a trench for a field oxide area, performing a second ion implantation process to form a second impurity area on a first side of the trench for the field oxide area, and performing a third ion implantation process to form a third impurity area on a second side of the trench for the field oxide area.

### BRIEF DESCRIPTION OF THE DRAWINGS

FIG. 1 is a plan view showing a memory cell when a self-aligned source (SAS) technology is not employed;

FIG. 2 is a plan view showing a memory cell when a SAS technology is employed;

FIG. 3 is a cross-sectional view taken along line I-I′ of FIG. 2;

FIGS. 4 to 9 are views showing a method for manufacturing a non-volatile memory device according to an embodiment;

FIG. 10 is a graph showing the comparison of surface resistances of various samples; and

FIG. 11 is an image showing a second ion implantation process according to an embodiment.

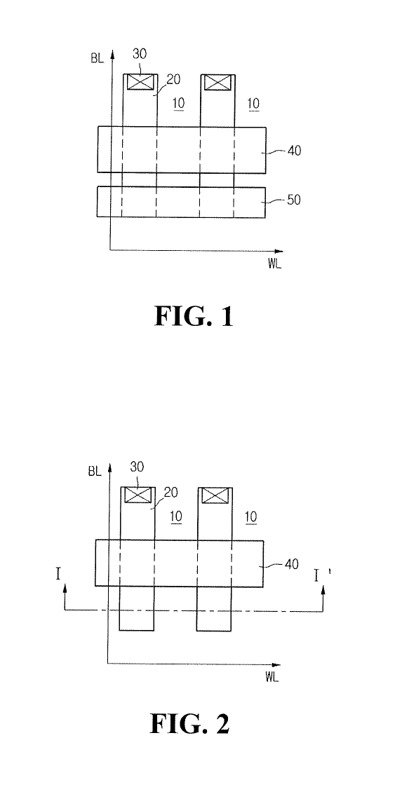

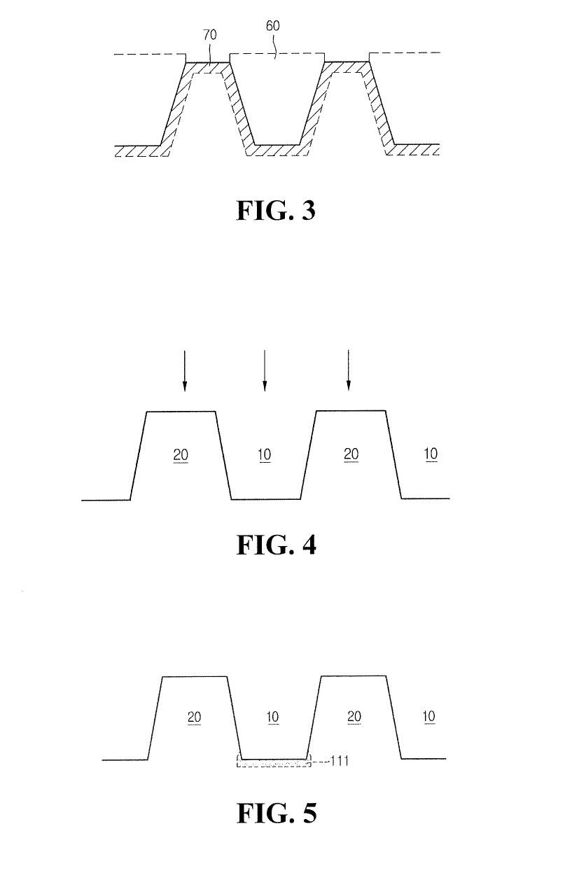

### DETAILED DESCRIPTION OF THE EMBODIMENTS

Hereinafter, a method for manufacturing a non-volatile memory according to embodiments of the present invention will be described in detail with respect to accompanying drawings.

FIGS. 4 to 11 are views showing a method for manufacturing a non-volatile memory device according to an embodiment.

Hereinafter, an ion implantation process for common source junction in a field oxide area 10 will be mainly described with respect to FIGS. 4 to 9, and details of the subsequent processes for constructing a gate stack including a control gate and a floating gate will be omitted.

Referring to FIG. 4, an active area 20 and a field oxide area 10 are defined on a semiconductor substrate, and a first ion implantation process is performed to form a SAS area in the field oxide area 10. The field oxide area can be a trench formed in the substrate.

In detail, the first ion implantation process can be vertically performed with respect to the semiconductor substrate. This first ion implantation process can be performed using arsenic (As). In the first ion implantation process, the As ions can be implanted with implantation energy 40 eV to 50 eV and a dose of 5×10¹⁵ ions/cm².

Referring to FIG. 5, a first impurity area 111 is formed in the field oxide area 10 through the first ion implantation process.

Accordingly, the first impurity area 111 is formed on the bottom surface of the field oxide area 10 in the profile of the field oxide area 10.

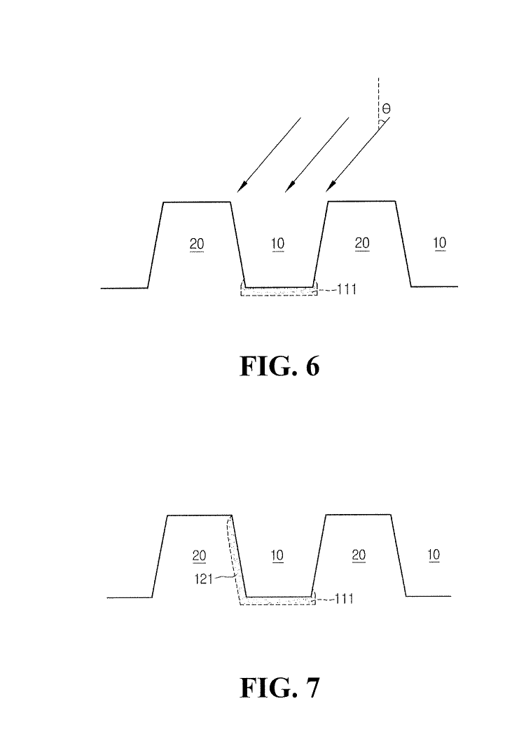

Thereafter, referring to FIG. 6, a second ion implantation process is performed to form the SAS area in the field oxide area 10. The second ion implantation process is performed with respect to the semiconductor substrate having the field oxide area 10 at a predetermined angle.

In detail, the second ion implantation process can be performed using As ions. The As ions can be implanted with implantation energy 40 eV to 50 eV and a dose in the range of 4.5×10¹⁵ ions/cm² to 5.5×10¹⁵ ions/cm².

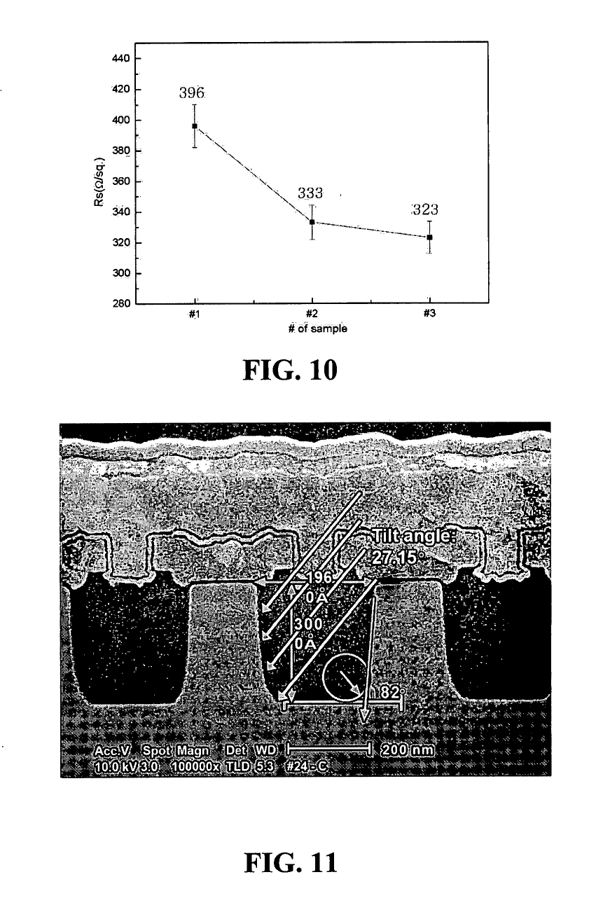

Hereinafter, detailed description will be made with reference to Table 1 and FIG. 10 regarding an ion implantation angle relative to the semiconductor substrate for the second ion implantation process.

TABLE 1

| (# of | | ion implantation | dose | ion implantation |
|---|---|---|---|---|
| sample) | Impurity | energy(eV) | (ions/cm²) | angle (°) |
| 1 | As | 45 | 5 × 10¹⁵ | 22 |
| 2 | As | 45 | 5 × 10¹⁵ | 25 |
| 3 | As | 45 | 5 × 10¹⁵ | 28 |
| 4 | As | 45 | 4.5 × 10¹⁵ | 30 |
| 5 | As | 45 | 4.5 × 10¹⁵ | 25 |
| 6 | As | 45 | 5 × 10¹⁵ | 25 |
| 7 | As | 50 | 4.5 × 10¹⁵ | 25 |
| 8 | As | 50 | 5 × 10¹⁵ | 25 |

When the second ion implantation process is performed under process conditions shown in Table 1, the surface resistances of the first to third samples can be seen in FIG. 10.

In the case of the first, second, and third samples, as the ion implantation angle is increased to 28°, the surface resistances are reduced. In particular, the third sample has the least surface resistance of 323 Ω/sq.

In addition, the resistance difference of the third and fourth samples (although it is not shown in FIG. 10) is 24 Ω/sq, and the resistance difference between the second and third samples is 10 Ω/sq. Accordingly, it can be recognized that the resistance difference between the second and third samples is smaller than the resistance difference of the third and fourth samples.

Therefore, it can be seen that electrical characteristics according to a dose as well as the ion implantation angle exert an influence on the surface resistance of the semiconductor device. Accordingly, the lowest surface resistance is obtained when the ion implantation angle is 28°, and a dose is 5×10¹⁵ ions/cm². FIG. 11 is an image showing the second ion implantation process. Referring to FIG. 7, the second impurity area 121 is formed at a side-wall of the field oxide area 10 through the second ion implantation process.

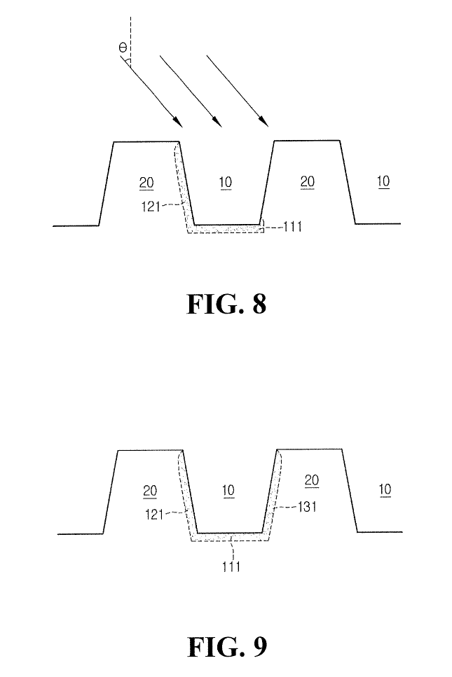

Thereafter, referring to FIG. 8, a third ion implantation process is performed to form an impurity area in the field oxide area 10. The third ion implantation process can have the same process conditions as those of the second ion implantation process.

Accordingly, as shown in FIG. 9, a third impurity area 131 is formed on the other side-wall of the field oxide area 10 through the third ion implantation process.

Although the second ion implantation process and the third ion implantation process are described as being sequentially performed, the second ion implantation process and the third ion implantation process can be simultaneously performed.

In addition, it is apparent to those skilled in the art that the process for forming a gate of the semiconductor device and a metal process for the connection between layers are further performed after impurity areas, in which As ions are implanted, are formed in the field oxide area 10.

As described above, according to an embodiment, impurity areas (SAS areas) are formed in the field oxide area such that the semiconductor device has lower surface resistance, thereby improving the characteristics of a manufactured non-volatile memory device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such a feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a non-volatile memory device, the method comprising:
performing an ion implantation process to form an impurity area in a trench for an isolation area formed on a substrate, wherein the ion implantation process is performed at least two times while varying ion implantation angles relative to the substrate.

2. The method according to claim 1, wherein the trench for an isolation area comprises a field oxide area.

3. The method according to claim 1, wherein the ion implantation process comprises:
a first ion implantation process for forming a first impurity area at a lower side of the trench, and
a second ion implantation process for forming a second impurity area at one side-wall of the trench.

4. The method according to claim 1, wherein the ion implantation process comprises:
a first ion implantation process for implanting ions in vertical direction relative to the substrate, and a second ion implantation for implanting ions at an angle of 28° relative to the substrate.

5. A method for manufacturing a non-volatile memory device having a self aligned source, the method comprising:
performing a first ion implantation process to form a first impurity area on a bottom surface of trench for an isolation area;
performing a second ion implantation process to form a second impurity area on a first side-wall of the trench; and
performing a third ion implantation process to form a third impurity area on the other side-wall of the trench.

6. The method according to claim 5, wherein the trench for an isolation area comprises a field oxide area.

7. The method according to claim 5, wherein the first ion implantation process, the second ion implantation process, and the third ion implantation process are performed using arsenic (As).

8. The method according to claim 5, wherein the second ion implantation process and the third implantation process are performed at an ion implantation angle of 28°.

9. The method according to claim 5, wherein As ions are implanted in the second ion implantation process and the third ion implantation process with implantation energy 40 eV to 50 eV and a dose of 5×10⁵ ions/cm².
